(19) United States
(12) Patent Application Publication
(10) Pub. No.: US 2014/0138761 A1
(43) Pub. Date: May 22, 2014

(54) SEMICONDUCTOR DEVICE AND MANUFACTURING METHOD OF SEMICONDUCTOR DEVICE

(71) Applicant: KABUSHIKI KAISHA TOSHIBA, Tokyo (JP)

(72) Inventors: Atsushi YAGISHITA, Kanagawa (JP); Tatsuo Izumi, Kanagawa (JP)

(73) Assignee: Kabushiki Kaisha Toshiba, Tokyo (JP)

(21) Appl. No.: 13/780,342

(22) Filed: Feb. 28, 2013

Related U.S. Application Data
(60) Provisional application No. 61/727,406, filed on Nov. 16, 2012.

(51) Int. Cl. H01L 29/792; H01L 29/66

(52) U.S. Cl. CPC H01L 29/792; H01L 29/66833
USPC 257/326; 438/591; 438/287

(57) ABSTRACT

According to one embodiment, a semiconductor device includes an active area that is formed on a semiconductor substrate, a trench that isolates the active area, a nitride film that is buried in the trench, an air gap that is formed above the nitride film along the trench, and a gate electrode that is formed on the active area to span the trench through the air gap.

### CROSS-REFERENCE TO RELATED APPLICATIONS

This application is based upon and claims the benefit of priority from Provisional Patent Application No. 61/727,406, filed on Nov. 16, 2012; the entire contents of which are incorporated herein by reference.

### FIELD

Embodiments generally relate to a semiconductor device and a manufacturing method of a semiconductor device.

### BACKGROUND

In NAND flash memories, there are cases in which an air gap is formed in a trench separating an active area of a memory cell in order to reduce parasitic capacitance between charge accumulating layers. When the depth of the air gap varies, coupling capacitance between memory cells may vary.

### BRIEF DESCRIPTION OF THE DRAWINGS

FIG. 1 is a perspective view illustrating a schematic configuration of a memory cell of a semiconductor device according to a first embodiment.

FIGS. 2A to 9C are cross-sectional views illustrating a manufacturing method of a memory cell of a semiconductor device according to a second embodiment.

FIG. 10 is a perspective view illustrating a schematic configuration of a memory cell of a semiconductor device according to a third embodiment.

FIGS. 11A to 19C are cross-sectional views illustrating a manufacturing method of a memory cell of a semiconductor device according to a fourth embodiment;

FIG. 20 is a perspective view illustrating a schematic configuration of a memory cell of a semiconductor device according to a fifth embodiment.

FIG. 21 is a perspective view illustrating a schematic configuration of a memory cell and a select gate transistor of a semiconductor device according to a sixth embodiment.

### DETAILED DESCRIPTION

According to an embodiment, an active area, a trench, a nitride film, an air gap, and a gate electrode are formed. The active area is formed on a semiconductor substrate. The trench separates the active area. The nitride film is buried in the trench. The air gap is formed the nitride film along the trench above. The gate electrode is formed on the active area to span the trench through the air gap.

Hereinafter, a semiconductor device and a manufacturing method thereof according to embodiments will be described in detail with reference to the accompanying drawings. In the following, a non-volatile semiconductor memory device will be described as an example of a semiconductor device, but the present invention is not limited to the following embodiments.

### First Embodiment

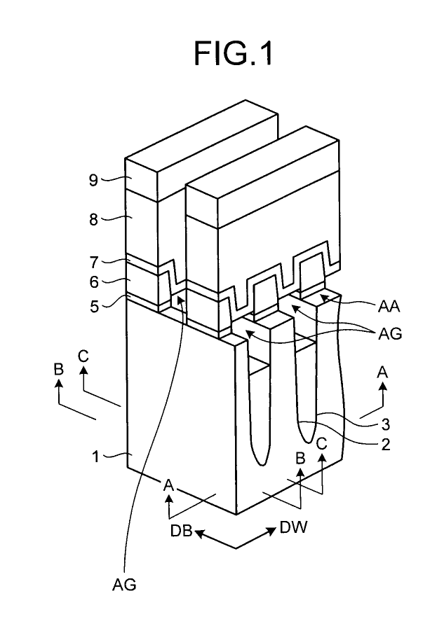

FIG. 1 is a perspective view illustrating a schematic configuration of a memory cell of a semiconductor device according to a first embodiment.

Referring to FIG. 1, a semiconductor substrate 1 includes a plurality of trenches 2 that extends in a column direction DB and is arranged in a row direction DW. An active area AA of a memory cell formed on the semiconductor substrate 1 is separated by the trench 2. The active area AA in the memory cell is referred to a channel region of a memory transistor formed in the memory cell and a region (for example, a source region and a drain region) between memory cells which are serially connected to each other. The semiconductor substrate 1 may be made of a material selected from, for example, Si, Ge, SiGe, SiC, SiSn, PbS, GaAs, InP, GaP, GaN, GaInAsP, or ZnSe.

A nitride film 3 is buried in the trench 2 continuously in the column direction DB. For example, a silicon nitride film may be used as the nitride film 3. An air gap AG is formed above the nitride film 3 along the trench 2. In FIG. 1, the lower end of the air gap AG is defined by the nitride film 3, and the upper end of the air gap AG is defined by the inter-electrode insulating film 7. The side of the air gap AG is defined by a tunnel insulating film 5, a charge accumulating layer 6, and an interlayer insulating film (not illustrated) which are formed on the side of the trench 2 or above the trench 2.

Further, in the active area AA, the charge accumulating layer 6 is formed with the tunnel insulating film 5 interposed therebetween for each memory cell. Here, an example in which the charge accumulating layer 6 is used as the floating gate electrode will be described. A charge trap film such as a silicon nitride film may be used as the charge accumulating layer 6. For example, a thermal oxide film or a thermal oxynitride film may be used as the tunnel insulating film 5. Alternatively, the CVD oxide film or the CVD oxynitride film may be used as the charge accumulating layer 6. Alternatively, an insulating film with Si interposed therein or an insulating film in which Si is buried in the form of a dot may be used as the charge accumulating layer 6. The charge accumulating layer 6 may be made of poly silicon in which an N-type impurity or a P-type impurity is doped or may be formed of a metal film or a poly metal film made of Mo, Ti, W, Al, Ta, or the like.

A control gate electrode 8 is formed in the row direction DW above the charge accumulating layer 6 with the inter-electrode insulating film 7 interposed therebetween. The control gate electrode 8 may pass above the active area AA to span the trench 2 through the air gap AG. The control gate electrode 8 may configure a part of a word line. Here, the control gate electrode 8 may be formed to face the sidewall of the charge accumulating layer 6 in the row direction DW in order to improve the coupling ratio between the charge accumulating layer 6 and the control gate electrode 8. A silicide layer 9 is formed on the control gate electrode 8. For example, a silicon oxide film or a silicon nitride film may be used as the inter-electrode insulating film 7. Alternatively, the inter-electrode insulating film 7 may have a stacking structure of a silicon oxide film and a silicon nitride film such as an ONO film. Alternatively, the inter-electrode insulating film 7 may be formed of a high-dielectric-constant film such as an aluminum oxide or a hafnium oxide or may have a stacking structure of a low-dielectric-constant film and a high-dielectric-constant film such as a silicon oxide film or a silicon nitride film. The control gate electrode 8 may be made of poly silicon in which an N-type impurity or a P-type impurity is doped. Alternatively, the control gate electrode 8 may be formed of a metal film or a poly metal film made of Mo, Ti, W, Al, Ta, or the like. When the control gate electrode 8 is formed of a metal film or a poly metal film, the silicide layer 9 may not be formed. For example, the silicide layer 9 may be made of CoSi, NiSi, PtSi, WSi, MoSi, or the like.

In FIG. 1, the air gap AG may be formed to penetrate into the upper portion of the trench 2 such that the bottom of the air gap AG reaches up to the position deeper than the lower surface of the charge accumulating layer 6. Further, the air gap AG may be continuously formed along the trench 2 to pass below the control gate electrode 8. The upper surface of the nitride film 3 buried in the trench 2 may be below the control gate electrode 8 and thus lower than the upper surface of the semiconductor substrate 1. Further, the lower surface of the control gate electrode 8 positioned above the trench 2 may be higher than the upper surface of the semiconductor substrate 1.

Here, as the nitride film 3 is buried in the trench 2, the etching rate by the fluoric acid group chemical can be set to be higher than that by the nitride film 3 when a coating oxide film is buried in the air gap AG. Thus, when the coating oxide film buried in the air gap AG is removed, the depth of the air gap AG in the trench 2 can become uniform, and a variation in the coupling capacitance between the memory cells can be reduced. Further, as the depth of the air gap AG in the trench 2 becomes uniform, when ion implantations are performed to make channel or extension regions of a memory cell, a variation in concentration profile thereof can be reduced.

In addition, since the air gap AG is formed to reduce the parasitic capacitance between the charge accumulating layers 6, the nitride film 3 is formed at the position sufficiently deeper than the upper surface of the semiconductor substrate 1. For example, as illustrated in FIG. 1, the depth of the air gap AG from the semiconductor substrate 1 (the distance between the upper surface of the nitride film 3 and the upper surface of the semiconductor substrate 1) is larger than the height of the air gap AG on the semiconductor substrate 1(the distance between the upper end of the air gap AG and the upper surface of the semiconductor substrate 1). As described above, since the nitride film 3 is formed at the position sufficient distant from the memory cell, after writing in and erasure are repeated, a possibility that the nitride film 3 will trap electrons is low, and accompanying adverse effects do not occur.

### Second Embodiment

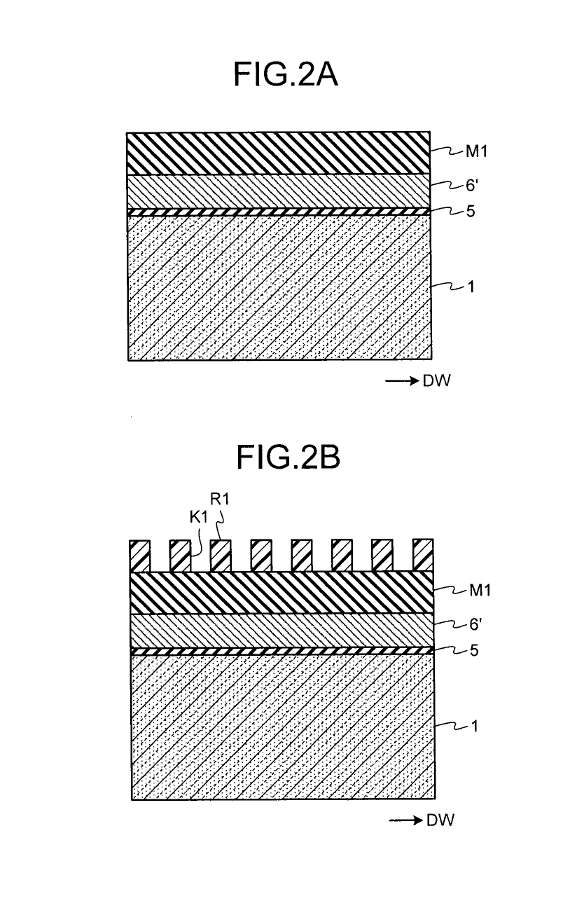

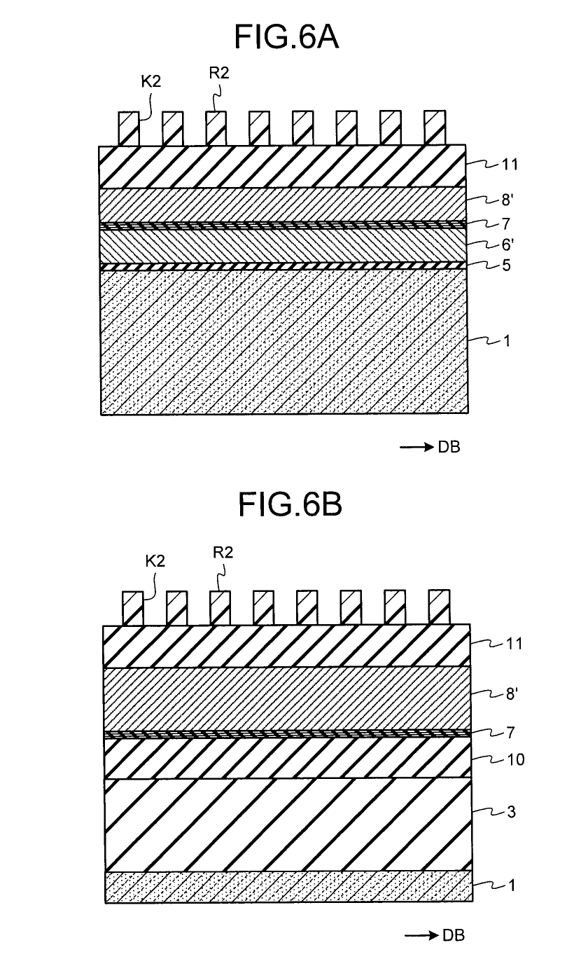

FIGS. 2A to 5A, FIGS. 6A to 9A, FIGS. 2B to 5B, FIGS. 6B to 9B, and FIGS. 7C to 9C are cross-sectional views illustrating a manufacturing method of a memory cell of a semiconductor device according to a second embodiment. Further, FIGS. 2A to 5A, FIGS. 2B to 5B, and FIG. 7A to FIG. 9A are cross-sectional views (taken along a line A-A of FIG. 1) taken along the control gate electrode 8 of FIG. 1 in the row direction DW, FIG. 6A and FIGS. 7B to 9B are cross-sectional views (taken along a line C-C of FIG. 1) taken along the active area AA of FIG. 1 in the column direction DB, and FIG. 6B and FIGS. 7C to 9C are cross-sectional views (taken along a line B-B of FIG. 1) taken along the trench 2 of FIG. 1 in the column direction DB.

Referring to FIG. 2A, a tunnel insulating film 5 is formed on a semiconductor substrate 1 using a technique such as thermal oxidization. The tunnel insulating film 5 may be formed by a nitriding process using an NO gas. For example, the film thickness of the tunnel insulating film 5 may be set to 7.5 nm. Then, a charge accumulating material 6′ is formed on the tunnel insulating film 5 using a technique such as the CVD. For example, the charge accumulating material 6′ may be made of poly silicon. For example, the film thickness of the charge accumulating material 6′ may be set to 50 nm. Then, a hard mask M1 is formed on the charge accumulating material 6′ using a technique such as the CVD. For example, the hard mask M1 may be formed of a silicon oxide film or a silicon nitride film.

Next, as illustrated in FIG. 2B, a resist pattern R1 with an opening portion K1 is formed on the hard mask M1 using the photolithography technique.

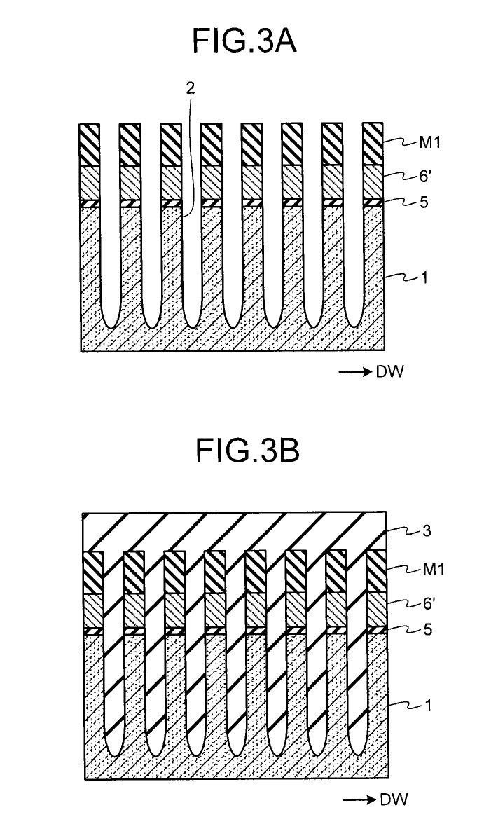

Next, as illustrated in FIG. 3A, the hard mask M1 is patterned using the resist pattern R1 as a mask, and then the charge accumulating material 6′, the tunnel insulating film 5, and the semiconductor substrate 1 are etched using the hard mask M1 as a mask to thereby form a trench 2 in the semiconductor substrate 1. In addition, a sidewall transfer process may be used when the trench 2 is formed in the semiconductor substrate 1.

Next, as illustrated in FIG. 3B, a nitride film 3 is formed on the hard mask M1 using a technique such as the low-pressure CVD to bury the whole trench 2.

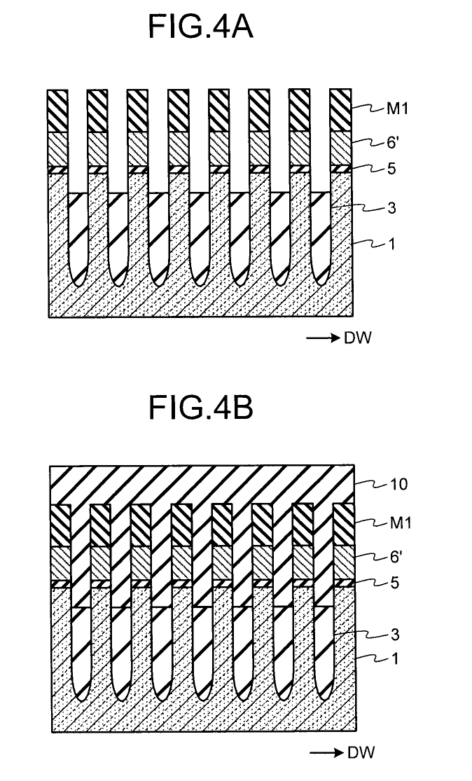

Next, as illustrated in FIG. 4A, the nitride film 3 is etched back so that the nitride film 3 is removed up to the mid-depth of the trench 2, and thus the surface of the hard mask M1 is exposed.

Next, as illustrated in FIG. 4B, an oxide film 10 is formed on the hard mask M1 using the coating technique to bury the whole trench 2. For example, the oxide film 10 may be formed of a coating oxide film such as polysilazane.

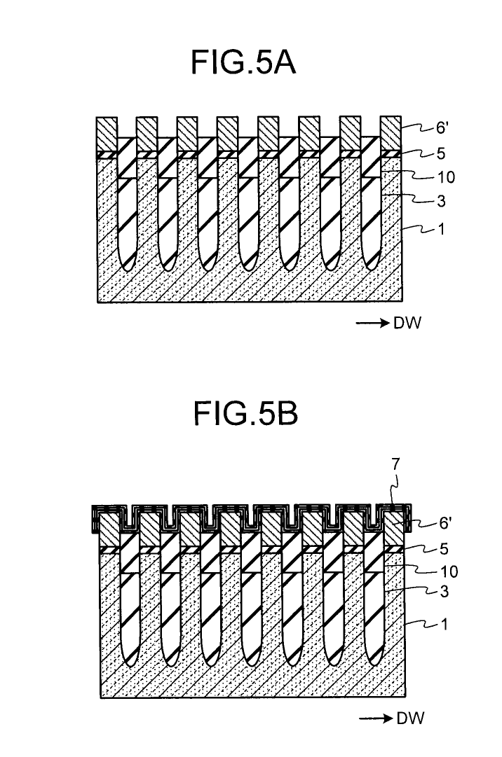

Next, as illustrated in FIG. 5A, the oxide film 10 is planarized using a technique such as the CMP, and then the oxide film 10 is etched back using a technique such as the wet etching, and thus a part of the oxide film 10 is removed, and a part of the sidewall of the charge accumulating material 6′ is exposed. Further, when the part of the sidewall of the charge accumulating material 6′ is exposed, the upper surface of the oxide film 10 is preferably higher than the upper surface of the tunnel insulating film 5. When the oxide film 10 is etched back using the wet etching, a fluoric acid group chemical such as a diluted hydrofluoric acid may be used. At this time, when the hard mask M1 is formed of a silicon oxide film, the hard mask M1 can be also removed when the oxide film 10 is etched back.

Next, as illustrated in FIG. 5B, an inter-electrode insulating film 7 is formed on the charge accumulating material 6′ using a technique such as the CVD to cover the sidewall of the charge accumulating material 6′. For example, the inter-electrode insulating film 7 may have a multi-layer structure such as an ONO film. For example, an equivalent oxide thickness of the inter-electrode insulating film 7 may be set to 11 nm.

Next, as illustrated in FIGS. 6A and 6B, a control gate electrode material 8′ and a cap insulating film 11 are sequentially formed on the inter-electrode insulating film 7 using a technique such as the CVD. For example, the control gate electrode material 8′ may be made of poly silicon. For example, the cap insulating film 11 may be formed of a silicon oxide film or a silicon nitride film. Then, a resist pattern film R2 with an opening portion K2 is formed on the cap insulating film 11 using the photolithography technique.

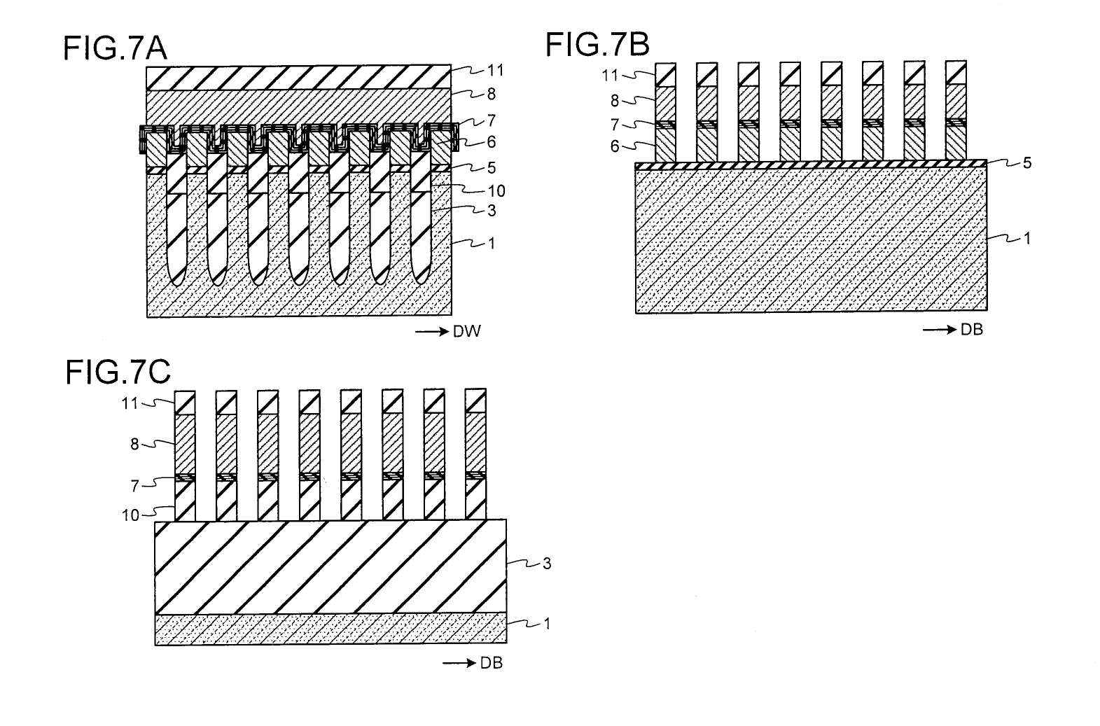

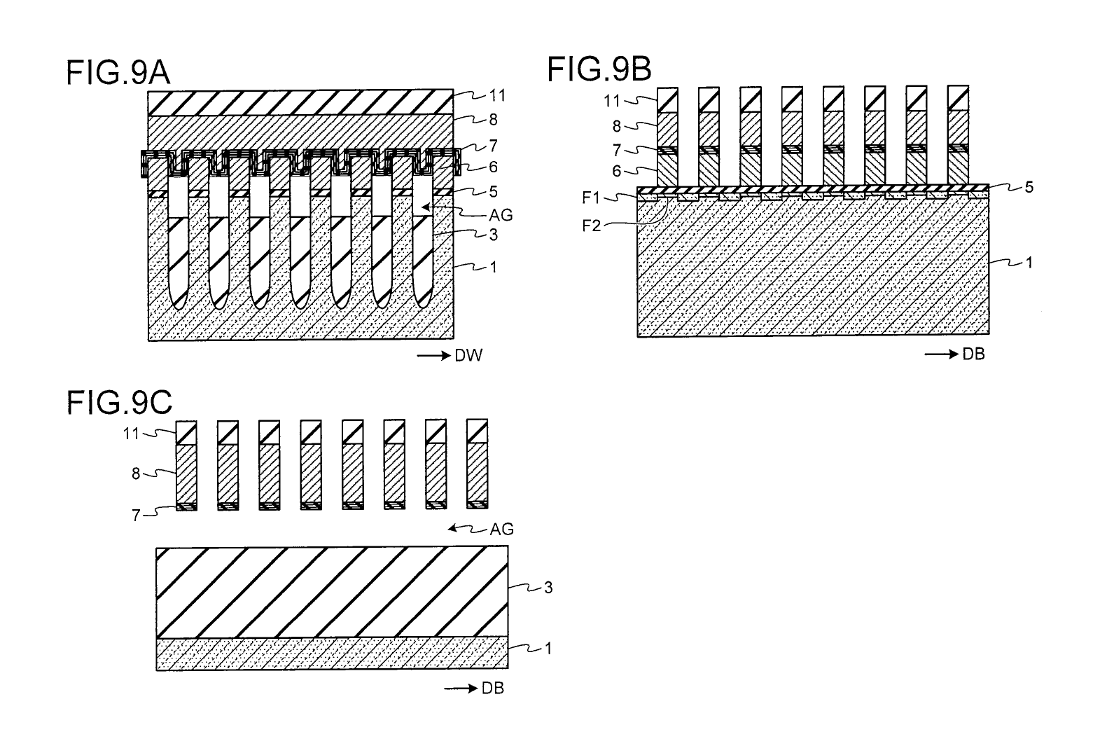

Next, the cap insulating film 11 is patterned using the resist pattern R2 with the opening portion K2 as a mask, and then the control gate electrode material 8′, the inter-electrode insulating film 7, and the charge accumulating material 6′ are etched using the cap insulating film 11 as a mask. As a result, as illustrated in FIGS. 7A to 7C, an isolated charge accumulating layer 6 is formed for each memory cell, and a control gate electrode 8 that is arranged above the charge accumulating layer 6 with the inter-electrode insulating film 7 interposed therebetween and extends in the row direction DW is formed. Here, even when the oxide film 10 is over-etched at the time of etching of the inter-electrode insulating film 7, etching is stopped by the nitride film 3. In FIG. 9C, the oxide film 10 is completely etched.

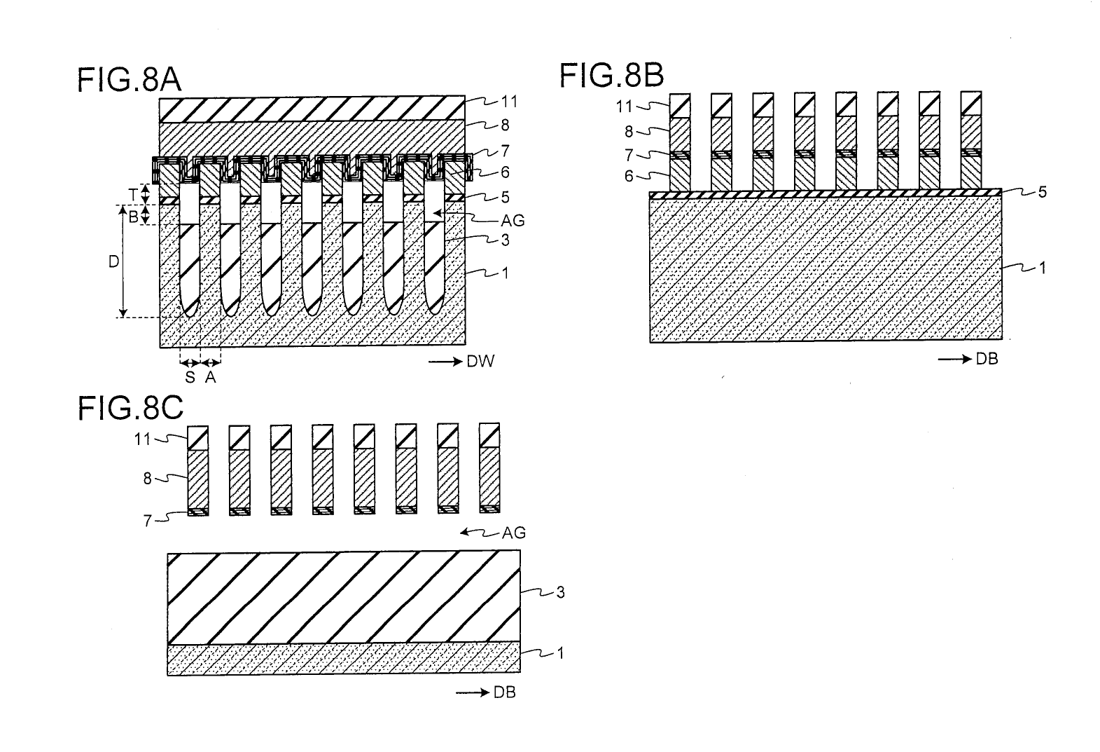

Next, as illustrated in FIGS. 8A to 8C, the oxide film 10 is removed along the trench 2 using a technique such as the wet etching, and an air gap AG is formed between the charge accumulating layers 6 which are adjacent to each other in the row direction DW. Further, when the oxide film 10 is removed by the wet etching, a fluoric acid group chemical such as a diluted hydrofluoric acid may be used. At this time, the fluoric acid group chemical invades under the control gate electrode 8, and thus the air gap AG can be formed continuously along the trench 2 to pass below the control gate electrode 8.

For example, the width S of the trench 2 is 22 nm, the width A of the active area AA may be set to 17 nm, the depth D of the trench 2 from the semiconductor substrate 1 may be set to 200 nm, the depth B of the air gap AG from the semiconductor substrate 1 may be set to 70 nm, and the height T of the air gap AG on the semiconductor substrate 1 may be set to 20 nm. The depth B of the air gap AG from the semiconductor substrate 1 is preferably 70 nm or more.

Here, as the nitride film 3 is buried below the oxide film 10, etching of the oxide film 10 can be stopped by the nitride film 3, and the depth of the air gap AG can be defined by the position of the nitride film 3. Thus, the depth of the air gap AG in the trench 2 can become uniform, and a variation in the coupling capacitance between the memory cells can be reduced.

Next, as illustrated in FIGS. 9A to 9C, first ion implantation is performed into the semiconductor substrate 1, and thus an impurity diffused layer F2, a channel region, is formed below the charge accumulating layer 6. In addition, second ion implantation is performed into the semiconductor substrate 1, and an impurity diffused layer F1, an extension region, is formed in the semiconductor substrate to reach an inside portion from an edge of the charge accumulating layer 6.

Generally, when there is a variation in the structure around a place in which an ion is implanted, there is a variation in the distribution of an ion to be implanted. In the present embodiment, the depth of the air gap AG in the trench 2 becomes uniform, and thus a variation in concentration profile can be reduced even when channel ion implantation and extension ion implantation are performed on the memory cell.

### Third Embodiment

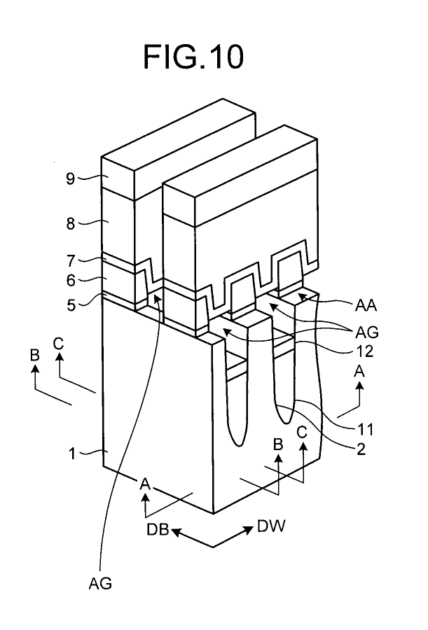

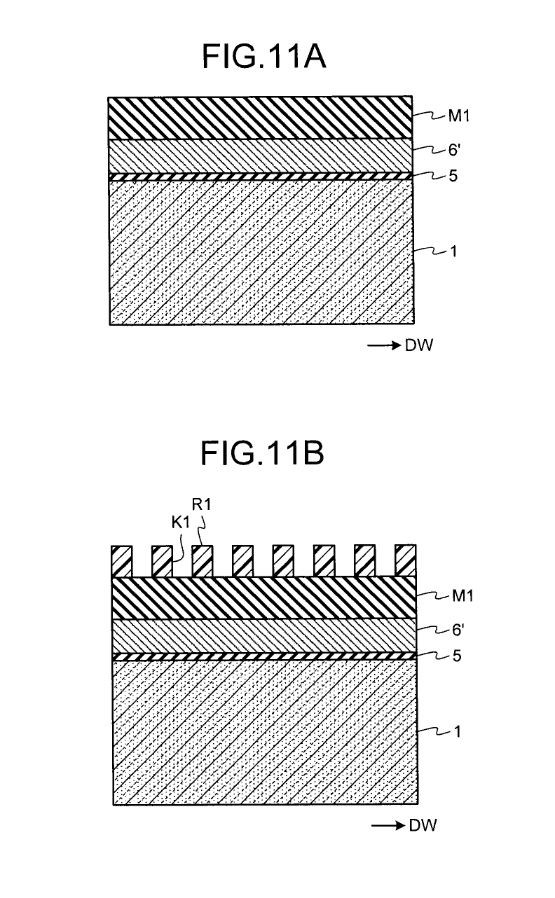

FIG. 10 is a perspective view illustrating a schematic configuration of a memory cell of a semiconductor device according to a third embodiment.

Referring to FIG. 10, in this memory cell, an oxide film 11 and a nitride film 12 are formed instead of the nitride film 3 of the memory cell of FIG. 1. Here, the oxide film 11 is buried up to the mid-depth of the trench 2. The nitride film 12 is formed on the oxide film 11, and the air gap AG is formed above the nitride film 12 along the trench 2.

Here, as the nitride film 12 is buried in the trench 2, the etching rate by the fluoric acid group chemical can be higher than that by the nitride film 12 when the coating oxide film is buried in the air gap AG. Thus, when the coating oxide film buried in the air gap AG is removed, the depth of the air gap AG in the trench 2 can become uniform, and a variation in the coupling capacitance between the memory cells can be reduced. Further, as the depth of the air gap AG in the trench 2 becomes uniform, a variation in concentration profile can be reduced even when channel ion implantation and extension ion implantation are performed on the memory cell.

Generally, when writing-in and erasure or the like are repeated on the nitride film 12, charges are likely to be accumulated. However, in the third embodiment, the oxide film 11 is buried below the nitride film 12, and thus the amount of charges trapped by the nitride film 12 can be reduced. Thus, even when the trench 2 is shallower than the structure of FIG. 1, an insulation property between the memory cells can be secured.

### Fourth Embodiment

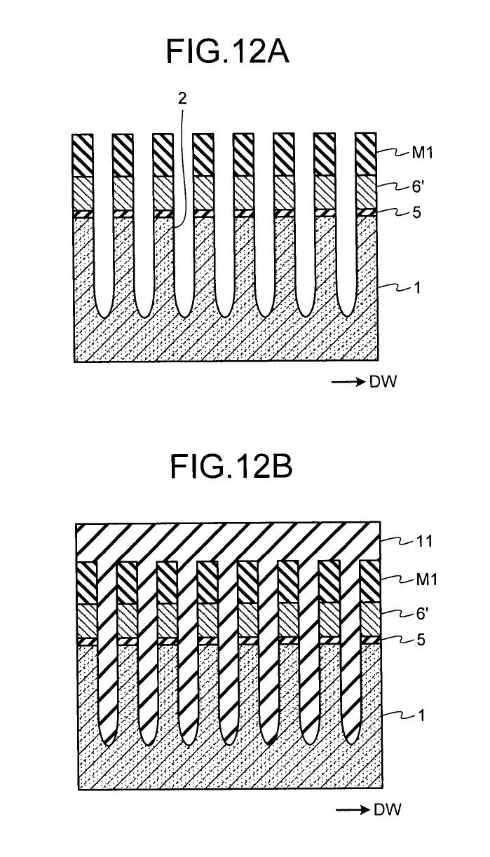

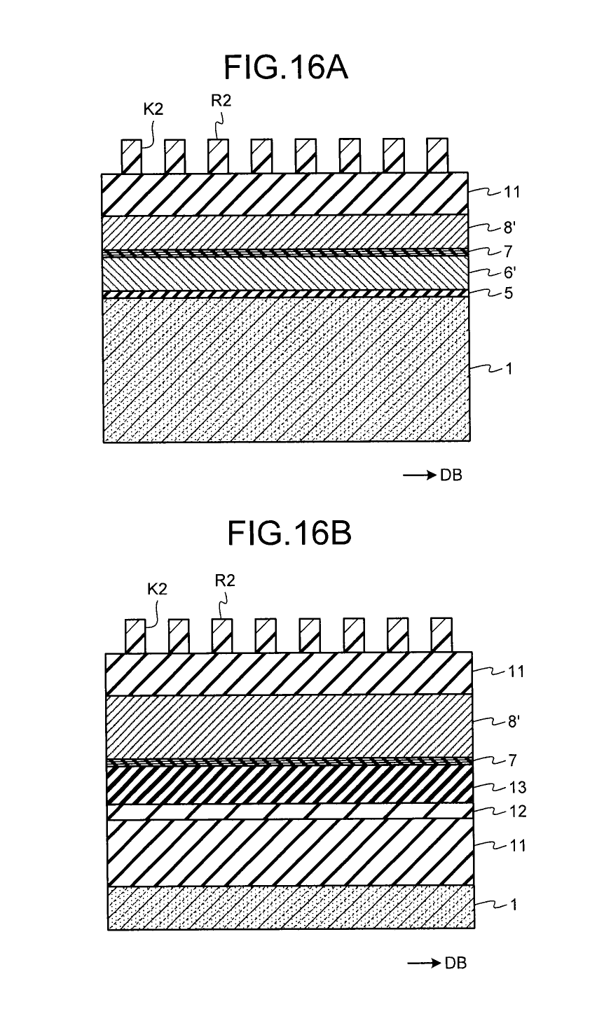

FIGS. 12A to 19A, FIGS. 12B to 21B, and FIGS. 17C to 19C are cross-sectional views illustrating a manufacturing method of a memory cell of a semiconductor device according to a fourth embodiment. Further, FIGS. 12A to 16A, FIGS. 12B to 16B, and FIGS. 17A to 19A are cross-sectional views (taken along a line A-A of FIG. 10) taken along the control gate electrode 8 of FIG. 10 in the row direction DW, FIG. 16A and FIGS. 17B to 19B are cross-sectional views (taken along a line C-C of FIG. 10) taken along the active area AA of FIG. 10 in the column direction DB, and FIG. 16B and FIGS. 17C to 19C are cross-sectional views (taken along a line B-B of FIG. 10) taken along the trench 2 of FIG. 10 in the column direction DB.

The initial process of the forth embodiment is the same as FIG. 2A to FIG. 3B of the second embodiment. Here, the description will proceed in connection with a subsequent process.

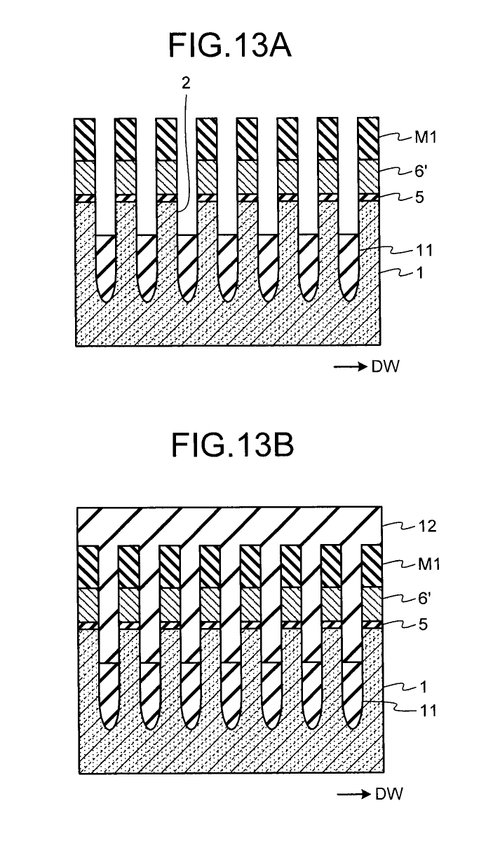

As illustrated in FIG. 13A, the oxide film 11 is planarized by a technique such as the CMP, and then the oxide film 11 is etched back, and thus the oxide film 11 is removed up to the mid-depth of the trench 2, and the surface of the hard mask M1 is exposed.

Next, as illustrated in FIG. 13B, the nitride film 12 is formed on the hard mask M1 using a technique such as the low-pressure CVD to bury the whole trench 2.

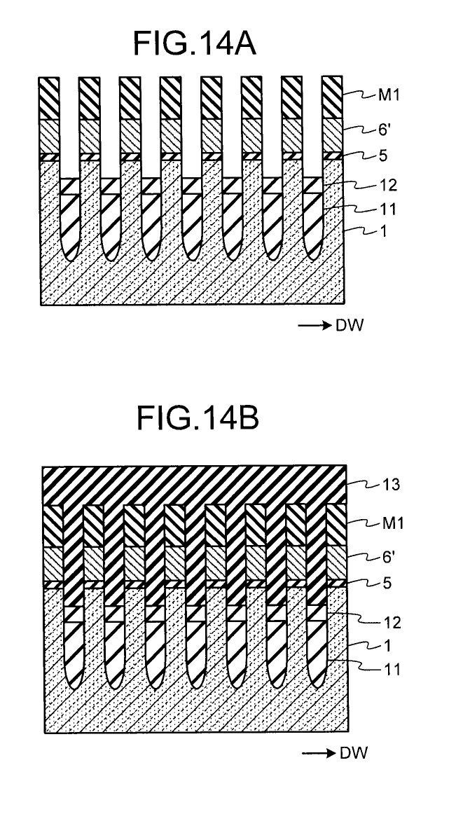

Next, as illustrated in FIG. 14A, the nitride film 12 is etched back to remove the nitride film 12 up to the mid-depth of the trench 2 so that the nitride film 12 remains on the oxide film 11.

Next, as illustrated in FIG. 14B, an oxide film 13 is formed on the hard mask M1 using the coating technique or the like to bury the whole trench 2. For example, the oxide film 13 may be formed of a coating oxide film such as polysilazane.

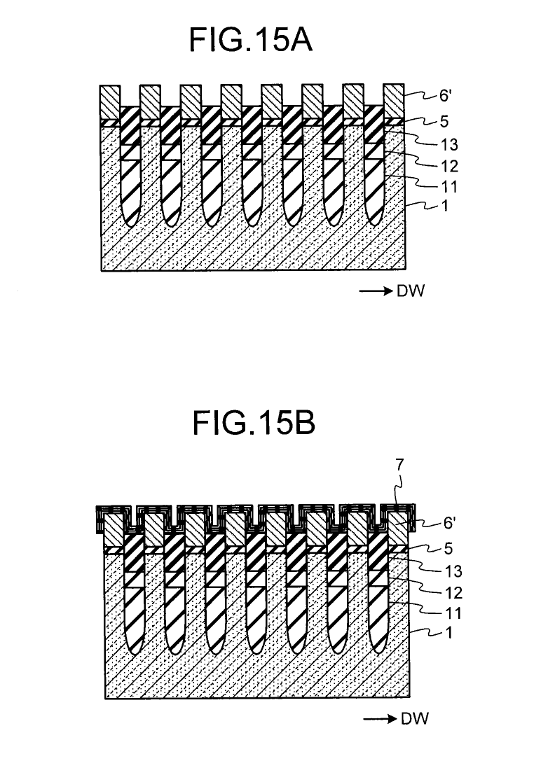

Next, as illustrated in FIG. 15A, the oxide film 13 is planarized by a technique such as the CMP, and then the oxide film 13 is etched back by a technique such as the we etching to remove a part of the oxide film 13 and expose a part of the sidewall of the charge accumulating material 6′. Further, when the part of the sidewall of the charge accumulating material 6′ is exposed, the upper surface of the oxide film 13 is preferably higher than the upper surface of the tunnel insulating film 5. Further, when the oxide film 13 is etched back by the wet etching, a fluoric acid group chemical such as a diluted hydrofluoric acid may be used. At this time, when the hard mask M1 is formed of a silicon oxide film, the hard mask M1 may be also removed when the oxide film 13 is etched back.

Next, as illustrated in FIG. 15B, an inter-electrode insulating film 7 is formed on the charge accumulating material 6′ using a technique such as the CVD to cover the sidewall of the charge accumulating material 6′.

Next, as illustrated in FIGS. 16A and 16B, a control gate electrode material 8′ and a cap insulating film 11 are sequentially formed on the inter-electrode insulating film 7 using a technique such as the CVD. For example, the control gate electrode material 8′ may be made of poly silicon. For example, the cap insulating film 11 may be formed of a silicon oxide film or a silicon nitride film. Then, a resist pattern film R2 with an opening portion K2 is formed on the cap insulating film 11 using the photolithography technique.

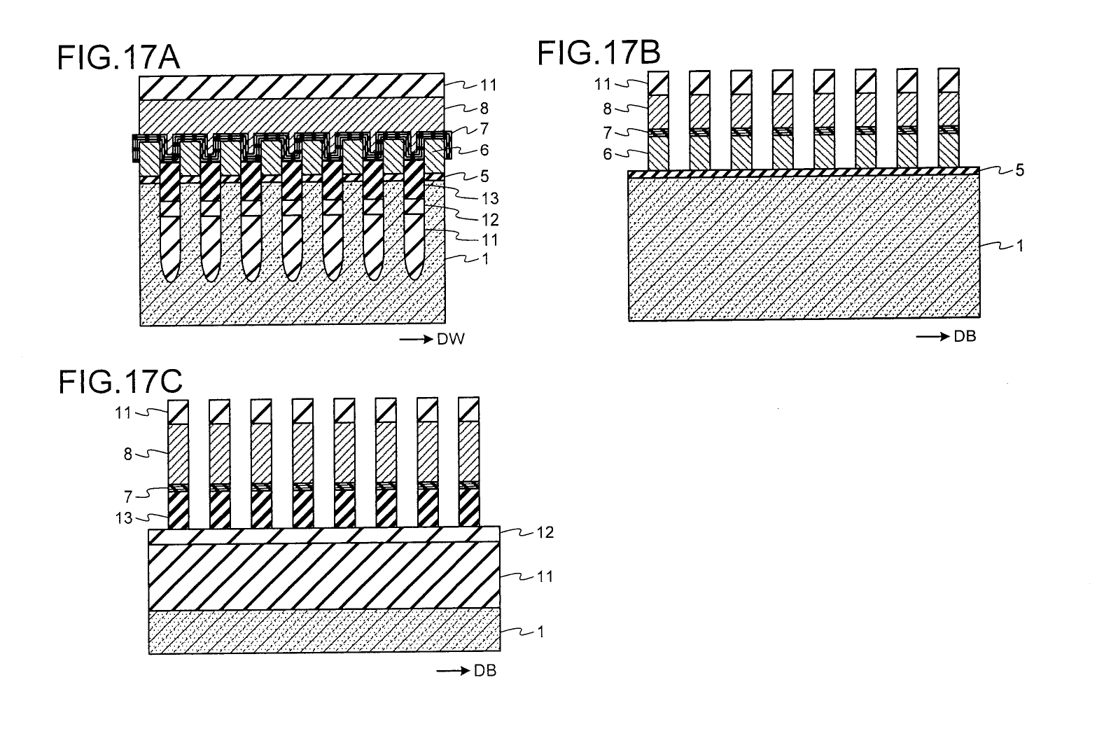

Next, the cap insulating film 11 is patterned using the resist pattern R2 with the opening portion K2 as a mask, and then the control gate electrode material 8′, the inter-electrode insulating film 7, and the charge accumulating material 6′ are etched using the cap insulating film 11 as a mask. As a result, as illustrated in FIGS. 17A to 17C, an isolated charge accumulating layer 6 is formed for each memory cell, and a control gate electrode 8 that is arranged above the charge accumulating layer 6 with the inter-electrode insulating film 7 interposed therebetween and extends in the row direction DW is formed. Here, even when the oxide film 13 is over-etched at the time of etching of the inter-electrode insulating film 7, etching is stopped by the nitride film 12. In FIG. 17C, the oxide film 13 is completely etched.

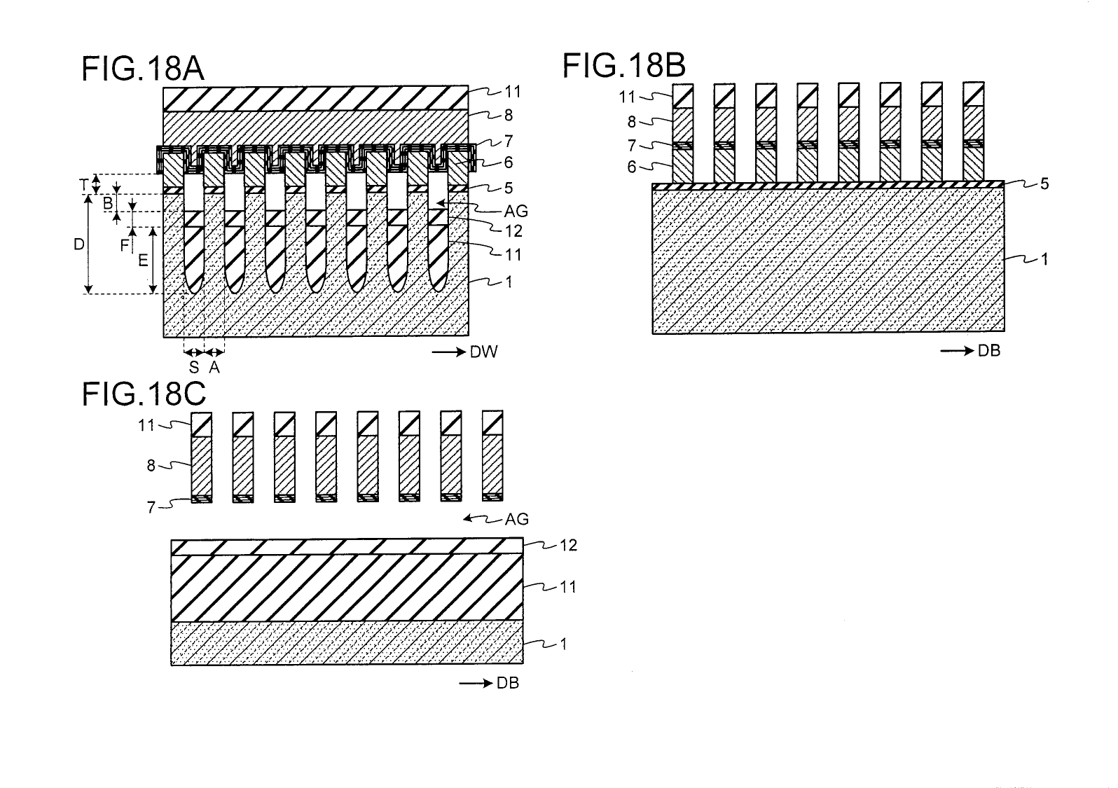

Next, as illustrated in FIGS. 18A to 18C, the oxide film 13 is removed along the trench 2 using a technique such as the wet etching, and an air gap AG is formed between the charge accumulating layers 6 which are adjacent to each other in the row direction DW. Further, when the oxide film 13 is removed by the wet etching, a fluoric acid group chemical such as a diluted hydrofluoric acid may be used. At this time, the fluoric acid group chemical invades under the control gate electrode 8, and thus the air gap AG can be formed continuously along the trench 2 to pass below the control gate electrode 8.

For example, the width S of the trench 2 is 22 nm, the width A of the active area AA may be set to 17 nm, the depth D of the trench 2 from the semiconductor substrate 1 may be set to 170 nm, the depth B of the air gap AG from the semiconductor substrate 1 may be set to 70 nm, the height T of the air gap AG on the semiconductor substrate 1 may be set to 20 nm, the film thickness E of the oxide film 11 may be set to 70 nm, and the film thickness F of the nitride film 12 may be set to 30 nm. The depth B of the air gap AG from the semiconductor substrate 1 is preferably 70 nm or more.

Here, as the nitride film 12 is buried below the oxide film 13, etching of the oxide film 13 can be stopped by the nitride film 12, and the depth of the air gap AG is defined by the position of the nitride film 12. Thus, the depth of the air gap AG in the trench 2 can become uniform, and a variation in the coupling capacitance between the memory cells can be reduced. Further, the oxide film 11 is buried below the nitride film 12, and thus the amount of charges trapped by the nitride film 12 can be reduced, and the depth of the trench 2 can be reduced.

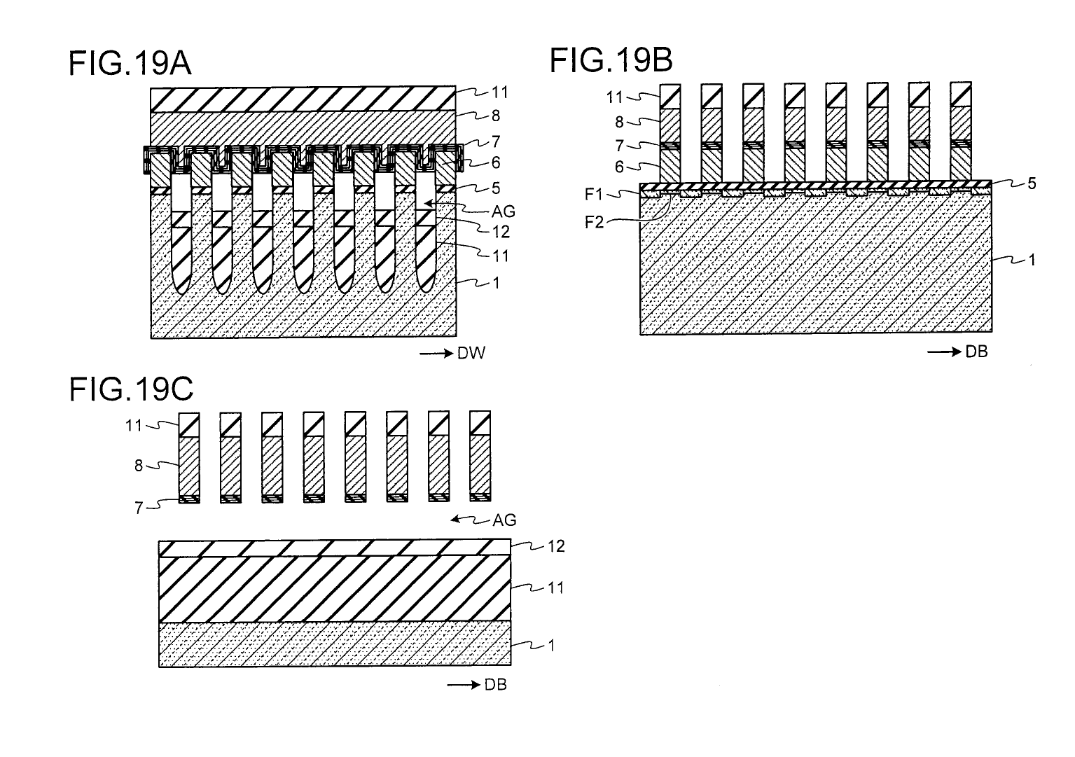

Next, as illustrated in FIGS. 19A to 19C, channel ion implantation is performed on the semiconductor substrate 1, and thus an impurity diffused layer F2 is formed below the charge accumulating layer 6. In addition, extension ion implantation is performed on the semiconductor substrate 1, and an impurity diffused layer F1 is formed to invade an end portion of the charge accumulating layer 6.

Generally, when there is a variation in the structure around a place in which an ion is implanted, there is a variation in the distribution of an ion to be implanted. In the present embodiment, as the depth of the air gap AG in the trench 2 becomes uniform, a variation in concentration profile can be reduced even when channel ion implantation and extension ion implantation are performed on the memory cell.

### Fifth Embodiment

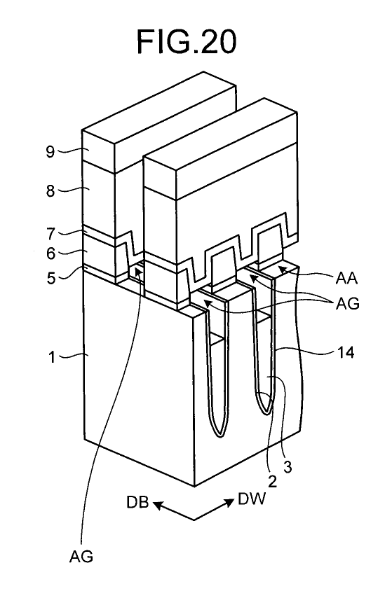

FIG. 20 is a perspective view illustrating a schematic configuration of a memory cell of a semiconductor device according to a fifth embodiment.

Referring to FIG. 20, in this memory cell, the sidewall insulating film 14 is formed on the sidewall of the trench 2 in addition to the configuration of the memory cell of FIG. 1. For example, the sidewall insulating film 14 may be formed of a silicon oxide film. For example, the film thickness of the sidewall insulating film 14 may be set to 2 nm.

The example of FIG. 20 illustrates the configuration in which the sidewall insulating film 14 is disposed in the memory cell of FIG. 1, but the sidewall insulating film 14 may be disposed in the memory cell of FIG. 10.

### Sixth Embodiment

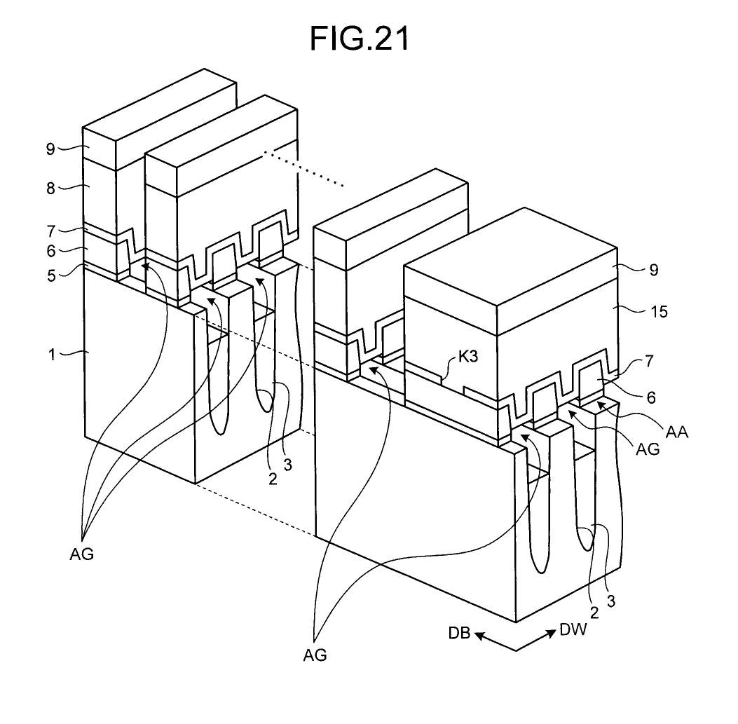

FIG. 21 is a perspective view illustrating a schematic configuration of a memory cell and a select gate transistor of a semiconductor device according to a sixth embodiment.

Referring to FIG. 21, in this memory cell, a select gate transistor is disposed in addition to the configuration of the memory cell of FIG. 1.

In other words, a plurality of trenches 2 extending in the column direction DB is arranged on a semiconductor substrate 1 in the row direction DW. The trench 2 separates the active areas AR of the memory cell and the select gate transistor formed on the semiconductor substrate 1 from each other. The active area AA in the select gate transistor refers to a channel region, a source region, and a drain region of the select gate transistor. The source region of the select gate transistor may be shared with the source region of the memory cell adjacent to the select gate transistor.

Further, the nitride film 3 is buried in the trench 2 continuously in the column direction DB. The air gap AG is formed above the nitride film 3 along the trench 2.

In the active area AA of the select gate transistor on the semiconductor substrate 1, the charge accumulating layer 6 is formed with the tunnel insulating film 5 interposed therebetween. Above the charge accumulating layer 6, a select gate electrode 15 extending in the row direction DW is formed with the inter-electrode insulating film 7 interposed therebetween. Here, the opening portion K3 is formed in the inter-electrode insulating film 7 on the charge accumulating layer 6 of the select gate transistor, and the charge accumulating layer 6 is connected with the select gate electrode 15 through the opening portion K3 of the inter-electrode insulating film 7. Here, the charge accumulating layer 6 of the select gate transistor is isolated by the trench 2, and thus the select gate transistor can be formed for each active area AA separated by the trench 2. The silicide layer 9 is formed on the select gate electrode 15.

In addition, when the air gap AG is formed to penetrate into the upper portion of the trench 2, the bottom of the air gap AG may reach up to the position deeper than the lower surface of the charge accumulating layer 6. Further, the air gap AG may be formed along the trench 2 to pass below the control gate electrode 8 and the select gate electrode 15.

In other words, the upper surface of the nitride film 3 buried in the trench 2 may be lower than the upper surface of the semiconductor substrate 1 below the control gate electrode 8 and the select gate electrode 15. Further, the lower surfaces of the control gate electrode 8 and the select gate electrode 15 positioned above the trench 2 may be higher than the upper surface of the semiconductor substrate 1.

Here, as the nitride film 3 is buried in the trench 2, when the coating oxide film is buried in the air gap AG, the etching rate by the fluoric acid group chemical can be higher than that by the nitride film 3. Thus, when the coating oxide film buried in the air gap AG is removed, the depth of the air gap AG in the trench 2 can become uniform, and a variation in coupling capacitance between the memory cells or between the select gate transistors can be reduced.

The example of FIG. 21 illustrates the configuration in which the select gate transistor is disposed in the memory cell of FIG. 1, but the select gate transistor may be disposed in the memory cell of FIG. 10 or the memory cell of FIG. 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
an active area that is formed in a semiconductor substrate;
a trench that separates the active area;
a nitride film that is buried in the trench; and
a gate electrode that spans over an air gap formed above the nitride film along the trench.

2. The semiconductor device according to claim 1,
wherein the nitride film is buried up to a bottom of the trench.

3. The semiconductor device according to claim 1, comprising,
an oxide film that is arranged below the nitride film to be buried in the trench.

4. The semiconductor device according to claim 3,
wherein the oxide film is made of polysilazane.

5. The semiconductor device according to claim 1, comprising,
a sidewall insulating film that is formed along an inner side of the trench.

6. The semiconductor device according to claim 1,
wherein a plurality of trenches extending in a column direction is formed,
the gate electrode includes a plurality of control gate electrodes extending in a row direction, and
the semiconductor device comprises a charge accumulating layer that is formed between the control gate electrode and the active area and is arranged in a form of a matrix in the row direction and the column direction.

7. The semiconductor device according to claim 6,
wherein the gate electrode includes a select gate electrode arranged in parallel to the control gate electrode, and the air gap is formed continuously across the control gate electrode and the select gate electrode.

8. The semiconductor device according to claim 1,
wherein a depth of the air gap from a surface of the semiconductor substrate is larger than a height of the air gap from the surface of the semiconductor substrate.

9. The semiconductor device according to claim 8,
wherein an upper end of the air gap is at a position higher than a lower surface of the charge accumulating layer.

10. The semiconductor device according to claim 9,
wherein above the air gap, a lower surface of the control gate electrode is at a position lower than an upper surface of the charge accumulating layer.

11. A manufacturing method of a semiconductor device, comprising:
depositing a charge accumulating material above a semiconductor substrate with a tunnel insulating film interposed therebetween;
forming a plurality of trenches extending through the charge accumulating material and the tunnel insulating film to reach an inner region of the semiconductor substrate in a column direction;
burying a first insulating film in the trench;
etching the first insulating film back to a predetermined depth of the trench;
burying a second insulating film having an etching rate by a fluoric acid group chemical higher than the first insulating film on the first insulating film in the trench;
forming an inter-electrode insulating film on the second insulating film and the charge accumulating material;
depositing a control gate electrode material on the inter-electrode insulating film;
patterning the control gate electrode material, the inter-electrode insulating film, and the charge accumulating material to form a plurality of charge accumulating layers which are isolated from one another, and to form a control gate electrode extending in a row direction; and
wet-etching the second insulating film using the fluoric acid group chemical to form an air gap arranged below the control gate electrode along the trench.

12. The manufacturing method of the semiconductor device according to claim 11, comprising:
performing ion implantation into a portion of the semiconductor substrate below the charge accumulating layer after the air gap is formed; and
performing ion implantation into a portion of the semiconductor substrate between the charge accumulating layers after the air gap is formed.

13. The manufacturing method of the semiconductor device according to claim 11,
wherein the first insulating film is formed of a nitride film, and the second insulating film is formed of an oxide film.

14. The manufacturing method of the semiconductor device according to claim 13,
wherein the second insulating film is made from polysilazane.

15. The manufacturing method of the semiconductor device according to claim 11, comprising,
forming a sidewall insulating film on a sidewall of the trench before burying the first insulating film along an inner side of the trench.

16. A manufacturing method of a semiconductor device, comprising:
depositing a charge accumulating material above a semiconductor substrate with a tunnel insulating film interposed therebetween;
forming a trench in the semiconductor substrate in a column direction through the charge accumulating material and the tunnel insulating film;
burying a first insulating film in the trench;
etching the first insulating film back to a first depth of the trench;
burying a second insulating film on the first insulating film in the trench;
etching the second insulating film back to a second depth lower than the first depth of the trench.
burying a third insulating film having an etching rate by a fluoric acid group chemical higher than the second insulating film on the second insulating film in the trench.
forming an inter-electrode insulating film on the third insulating film and the charge accumulating material;
depositing a control gate electrode material on the inter-electrode insulating film;
patterning the control gate electrode material, the inter-electrode insulating film, and the charge accumulating material to form a charge accumulating layer which is isolated for each memory cell, and forming a control gate electrode extending in a row direction; and
wet-etching the third insulating film using the fluoric acid group chemical to form an air gap arranged below the control gate electrode along the trench.

17. The manufacturing method of the semiconductor device according to claim 16, comprising:
performing ion implantation into a portion of the semiconductor substrate below the charge accumulating layer after the air gap is formed; and
performing ion implantation into a portion of the semiconductor substrate between the charge accumulating layers after the air gap is formed.

18. The manufacturing method of the semiconductor device according to claim 16,
wherein the first insulating film and the third insulating film are formed of an oxide film, and the second insulating film is formed of a nitride film.

19. The manufacturing method of the semiconductor device according to claim 18,
wherein the first insulating film and the third insulating film are made from polysilazane.

20. The manufacturing method of the semiconductor device according to claim 16, comprising,
forming a sidewall insulating film along an inner side of the trench before burying the first insulating film in the trench.
